(19) United States
(12) Patent Application Publication
(10) Pub. No.: US 2024/0371596 A1
(43) Pub. Date: Nov. 7, 2024

(54) MULTIPLE CHARGED PARTICLE BEAM SYSTEM WITH A MIRROR MODE OF OPERATION, METHOD FOR OPERATING A MULTI-BEAM CHARGED PARTICLE MICROSCOPE SYSTEM WITH A MIRROR MODE OF OPERATION AND ASSOCIATED COMPUTER PROGRAM PRODUCT

(71) Applicant: Carl Zeiss MultiSEM GmbH, Oberkochen (DE)

(72) Inventors: Ingo Mueller, Aalen (DE); Claudia Lumpp, Neu-Ulm (DE); Stefan Schubert, Oberkochen (DE); Yanko Sarov, Aalen (DE)

(21) Appl. No.: 18/778,496

(22) Filed: Jul. 19, 2024

Related U.S. Application Data
(63) Continuation of application No. PCT/EP2023/025010, filed on Jan. 17, 2023.

(30) Foreign Application Priority Data
Jan. 25, 2022 (DE) 10 2022 200 807.3

(51) Int. Cl. H01J 37/147; H01J 37/10; H01J 37/28

(52) U.S. Cl. CPC H01J 37/1477; H01J 37/10; H01J 37/28; H01J 2237/21; H01J 2237/221

(57) ABSTRACT

A multi-beam charged particle microscope system, having a mirror mode of operation, can be operated to record a stack of images in a mirror imaging mode. The stack of images comprises at least two images of two different settings of at least on multi-aperture element, for example a focus stack, which allows the multi-beam charged particle microscope system to be inspected and recalibrated thoroughly. Related methods computer program products are disclosed.

### CROSS-REFERENCE TO RELATED APPLICATIONS

The present application is a continuation of, and claims benefit under 35 USC 120 to, international application No. PCT/EP2023/025010, filed Jan. 17, 2023, which claims benefit under 35 USC 119 of German Application No. 10 2022 200 807.3, filed Jan. 25, 2022. The entire disclosure of each of these applications is incorporated by reference herein.

### FIELD

The disclosure relates to particle beam systems which operate with a multiplicity of charged particle beams.

### BACKGROUND

Similar to single-beam particle microscopes, multi-beam particle microscopes can be used to analyse objects on a microscopic scale. Images of an object that represent a surface of the object, for example, can be recorded using these particle microscopes. In this way, for example the structure of the surface can be analysed. While in a single-beam particle microscope a single particle beam of charged particles, such as, for example, electrons or ions, is used to analyse the object, in a multi-beam particle microscope, a plurality of particle beams is used for this purpose. The plurality of the particle beams, also referred to as a bundle, are directed at the surface of the object at the same time, as a result of which a significantly larger area of the surface of the object can be sampled and analysed as compared with a single-beam particle microscope within the same period of time.

WO 2005/024 881 A2 discloses a multi-beam charged particle microscope system in the form of an electron microscopy system which operates with a multiplicity of electron beams in order to scan an object to be examined using a bundle of electron beams in parallel. The bundle of electron beams is generated by an electron beam generated by an electron source being directed at a multi-aperture plate having a multiplicity of openings. One portion of the electrons of the electron beam strikes the multi-aperture plate and is absorbed there, and another portion of the beam passes through the openings in the multi-aperture plate, and so an electron beam is shaped in the beam path downstream of each opening, the cross section of the electron beam being defined by the cross section of the opening. Furthermore, suitably chosen electric fields provided in the beam path upstream and/or downstream of the multi-aperture plate have the effect that each opening in the multi-aperture plate acts as a lens on the electron beam passing through the opening, and so the electron beams are focused in a plane situated at a distance from the multi-aperture plate. The plane in which the foci of the electron beams are formed is imaged by a downstream optical unit onto the surface of the object to be examined, such that the individual electron beams strike the object in a focused manner as primary beams. There they generate interaction products, such as back-scattered electrons or secondary electrons, emanating from the object, which are shaped to form secondary beams and are directed at a detector by a further optical unit. There each of the secondary beams strikes a separate detector element such that the electron intensities detected by the detector element provide information relating to the object at the location at which the corresponding primary beam strikes the object. The bundle of primary beams is scanned systematically over the surface of the object in order to generate an electron micrograph of the object in the manner that is customary for scanning electron microscopes.

In practice, multi-beam charged particle microscope systems are often operated continuously with a high throughput. An example of this is the inspection of semiconductors. Frequent or regular system monitoring is typically used, for example in the case of continuous operation and/or in the case of a high throughput. By way of example, it is conventional to this end to carry out system monitoring and recalibration using a test sample.

The so-called mirror mode of operation (“mirror mode”) offers a system monitoring and calibration option in the case of single beam systems. By way of example, the latter is described in U.S. Pat. No. 7,521,676 B2. In this case, work is carried out using a planar electron beam, i.e., a non-focused electron beam, which is directed in the direction of a sample but is at least partly reflected upstream thereof. This likewise allows defects to be recognized in the case of semiconductors. Although the document also briefly touches on a mirror mode of operation for a multi-beam charged particle microscope system, the peculiarities of multi-beam charged particle microscope systems remain unconsidered in that case.

US 2008/0 073 533 A1 discloses a further single beam system which can be operated in a mirror mode of operation. The method serves to characterize insulator properties and it discloses the targeted charging or the charge capture of insulators when high electric field strengths are present. U.S. Pat. No. 11,049,686 BB proposes the application of the mirror mode for the investigation of samples. In the mirror mode, sample charging by the irradiation with primary charged particles can be prevented.

In patent DE 102020121132 B3, the applicant has discussed the application of the mirror mode of operation for system monitoring and calibration of multi-beam charged particle microscope systems. The mirror mode is demonstrated as a powerful method to inspect different planes of elements of a multiple beam system, such as pupil planes or stop planes. The approach provided in DE 102020121132 B3 can exhibit accuracy if higher order aberrations of the plurality of primary beamlets are concerned. While with the methods and system of the DE 102020121132 B3, first order aberrations can be detected, higher order aberrations such as field curvature, coma or telecentricity aberration cannot easily be detected.

The German patent application DE 10 2013 016 113 A1 discloses a multi-beam particle microscope and details in relation to a detection system. The latter may contain a combination of a scintillator plate and a light detector. Additionally, the provision of a light-optical camera is disclosed, as a result of which a light-optical image of the scintillator plate is detectable. The document neither discloses nor suggests a mirror mode of operation.

### SUMMARY

The disclosure seeks to improve existing multi-beam charged particle microscope systems. For example, the disclosure seeks to provide improved options for system monitoring and calibration, which take account of the peculiarities of multi-beam charged particle microscope systems.

The disclosure seeks to improve mirror modes of operation, such as for determining the properties of a plurality of primary beamlets of a multi-beam charged particle microscope system. It is desirable to integrate these into existing systems, such as in flexible and efficient fashions.

According to an aspect, the disclosure provides an advanced method of determining an imaging property of a multi-beam charged particle microscope. For the determination of an imaging property, the multi-beam charged particle microscope is switched from a first or normal mode of operation into a mirror mode of operation. In an example, the switching comprises the step of positioning an electrostatic mirror element in the proximity of an image plane of the multi-beam charged particle microscope. The electrostatic mirror element is provided with a voltage UR corresponding to a kinetic energy TPE of the primary charged particles. The voltage UR is controlled to exceed the kinetic energy TPE by a small amount of for example 50V, such that the primary electrons are decelerated down to a kinetic energy of zero at a point of reversal outside of the electrostatic mirror element. The primary electrons are then accelerated in reverse direction by the same decelerating electrical field generated by voltage UR and the primary electrons are therefore reflected to form a plurality of reflected primary electron beams. According to the disclosure, a stack of L mirror images is acquired from the reflected primary electron beams by an image sensor of a detection unit.

For each image of the stack of L mirror images, a driving voltage of at least one electrode of an active multi-aperture array element is changed. Therefore, each mirror image corresponds to a different driving voltage provided to an active multi-aperture array element. From the stack of L mirror images, an image performance of at least one primary beamlet is be determined from the stack of mirror images.

The stack of L mirror images comprises at least L=two, for example L=3 mirror images, for example corresponding to a focus stack through the plurality of primary charged particle beamlets. From the shapes and positions of the plurality of primary charged particle beamlets within each of the mirror images, a higher order aberration such as an astigmatism, field curvature, a coma aberration, a telecentricity aberration, or even higher order aberrations can be determined.

According to an embodiment of the disclosure, the advanced method of mirror mode operation is performed with a field lens in an off state, such that no intermediate focus points of the plurality of primary charged particle beamlets are formed in an intermediate image plane of the multi-beam charged particle microscope. According to this method, for example defects of a multi-aperture array element can be determined. In another example, a telecentricity of the plurality of primary charged particle beamlets can be determined.

According to an embodiment of the disclosure, the method of mirror mode operation is performed with a field lens in an on state and the stack of mirror images correspond for example to a stack of images through the focus position of the plurality of primary charged particle beamlets. According to this method, for example wavefront aberrations of at least one primary charged particle beamlet can be determined.

According to an example of the embodiments, the driving voltage is driving an array of ring electrodes of an active multi-aperture array element. An active multi-aperture array element in this example can be formed as an array of micro-lenses, configured for changing a focusing power. According to an alternative example of the embodiments, the driving voltage drives at least an electrode of an array of multi-pole elements of an active multi-aperture array element, which is configured for changing an astigmatism or a deflection angle of at least one primary beamlet for each image of the stack of mirror images. Thereby, a focus stack of mirror images or a stack of mirror images with for example different magnitudes of an astigmatism can be recorded.

Typically, the stack of L mirror images is generated by changing the driving voltage of at least one electrode of an active multi-aperture array element. In an example, the amount of change is about +/−10% of the maximum voltage range of the driving voltage of the at least one electrode of the active multi-aperture array element. In an example, the amount of change is about +/−30% of the maximum voltage range of the driving voltage of the at least one electrode of the active multi-aperture array element. For example, a first mirror image is generated a −30% of the maximum voltage range, a second mirror image is generated at 0% of the maximum voltage range of the driving voltage, and a third mirror image is generated at +30% of the maximum voltage range of the driving voltage. In an example, change is about +/−100% of the maximum voltage range of the driving voltage. For example, a maximum voltage range for ring electrodes of an active array of micro-lenses is about 100V, or between −100V and +100V. For example, a maximum voltage range for an electrode of an array of multi-pole elements is about 1V, or between −1V and +1V.

According to an example, a method of operating in a mirror mode further comprises a change of a magnification of a detection unit by changing a driving current of magnetic lenses of the detection unit.

According to an example, the method of determining an imaging property of a multi-beam charged particle microscope comprises a step of triggering a calibration and/or cleaning step of the multi-beam charged particle microscope. For example, when a defect of a multi-aperture array element is determined, a cleaning step of the multi-aperture array element can be triggered and performed.

According to an embodiment of the disclosure, a method of calibrating a mirror mode of operation of a multi-beam charged particle microscope is provided. The calibration method comprises the steps of selecting a mirror mode of operation and selecting a decelerating voltage UR to exceed a kinetic energy TPE of the primary electrons when exiting an objective lens or a final electrode of the multi-beam charged particle microscope. According to the method, the decelerating voltage UR can be provided via a voltage supply unit to a sample stage for generating a decelerating electrical field below the objective lens or the final electrode of the multi-beam charged particle microscope. In an example, an electrostatic mirror electrode is provided on the sample stage and positioned by the sample stage in the beam path of the primary electron beamlets. Thereby, a homogeneous and predetermined decelerating electrical field for reflecting the plurality of primary charged particle beamlets is provided. According to the calibration method, an object irradiation unit is adjusted to achieve a telecentric bundle formed by a plurality of J primary beamlets in the decelerating electrical field. Thereby it is maintained that the plurality of reflected electron beam spots at an image sensor do not move during acquisition of an image step due to a deviation of a telecentricity. The calibration method further comprises the step of adjusting a magnification of a detection unit to form the plurality of reflected primary electron beam spots on the image sensor or image detector. The calibration method further comprises the step of selecting a sequence of L driving voltages within a voltage range and recording a stack of L primary electron mirror images with the image detector. During each recording, a different driving voltage of the sequence of driving voltages is applied to at least one electrode of an active multi-aperture element. After verification of the performance of the method of determining an imaging property of a multi-beam charged particle microscope, the setting parameters selected and determined in the calibration method are stored and attributed to a mirror mode for repeated later use of the method of determining an imaging property of a multi-beam charged particle microscope.

According to an example, a multi-beam charged particle microscope for inspecting a wafer with a plurality of J primary charged particle beamlets comprises a stage for loading, holding the wafer and an electrostatic mirror. The stage is connected to a voltage supply unit for providing during use a voltage UR to the electrostatic mirror, wherein the voltage UR is different to the voltage Uₛₐₘₚₗₑ provided to the wafer during an inspection task. In an example, the electrostatic mirror can also be mounted on a second stage connected to a voltage supply unit for providing during use a voltage UR to the electrostatic mirror. The multi-beam charged particle microscope further comprises an active multi-aperture array with at least an electrode at each aperture provided for individually influencing during use each primary charged particle beamlet. The multi-beam charged particle microscope further comprises a control unit, which is configured for switching during use from a first or normal mode of operation into a second or mirror mode of operation. For switching to the second or mirror mode of operation, the control unit is configured to align the electrostatic mirror at a predetermined position in proximity of an object plane of the charged particle microscope. During the second mode of operation, the control unit is configured to provide the voltage UR to the electrostatic mirror. During the second or mirror mode of operation, the control unit is further configured to acquire a stack of L mirror images with a change of a driving voltage of at least one electrode of the active multi-aperture array, such that each mirror image corresponds to a different driving voltage. The multi-beam charged particle microscope further comprises a detection unit with a plurality of charged particle lenses. The control unit is further configured to adjust in the second or mirror mode a magnification of the detection unit to a second magnification different to a first magnification of a first mode of operation. The second magnification can be adjusted to a larger magnification than the first magnification.

According to an example, the disclosure relates to a computer program product having a program code for carrying out the method as described above in a plurality of embodiment variants. In this case, the program code can be subdivided into one or more partial codes. It is appropriate, for example, to provide the code for controlling the multi-beam charged particle microscope system in the normal mode of operation separately in one program part, while another program part contains the routines for operating the multi-beam charged particle microscope system in the mirror mode of operation.

However, other divisions of the code or even no divisions of the code into subregions are also possible as a matter of principle.

Various embodiments of the disclosure can be combined with one another in full or in part. Only technical contradictions are not to occur in such a combination of embodiment variants.

### BRIEF DESCRIPTION OF THE DRAWINGS

The disclosure will be understood even better with reference to the accompanying figures, in which:

FIG. 1 is a schematic illustration of a multi-beam charged particle microscope;

FIG. 2 illustrates a plurality of image spots of secondary particles on a detector;

FIG. 3 illustrates the multi-beam charged particle microscope in an example of a mirror mode of operation;

FIG. 4 illustrates a plurality of image spots of reflected primary charged particles on the detector at a first driving voltage of an active multi-aperture array;

FIG. 5 illustrates a plurality of image spots of reflected primary charged particles on the detector at a second driving voltage of the active multi-aperture array;

FIG. 6 illustrates a plurality of image spots of reflected primary charged particles on the detector at the first driving voltage of an active multi-aperture array in presence of aberrations or defects of individual beamlets;

FIG. 7 illustrates a plurality of image spots of reflected primary charged particles on the detector at the second driving voltage of an active multi-aperture array in presence of aberrations or defects of individual beamlets;

FIG. 8 illustrates the trajectories of the image spots of reflected primary charged particles on the detector over a plurality of driving voltages of an active multi-aperture array;

FIG. 9 illustrates the multi-beam charged particle microscope in a second example of a mirror mode of operation with a first driving voltage of an active multi-aperture array;

FIG. 10 illustrates the multi-beam charged particle microscope in a second example of a mirror mode of operation with a second driving voltage of an active multi-aperture array;

FIG. 11 illustrates the multi-beam charged particle microscope in a third example of a mirror mode of operation with an active multi-aperture array formed as a multi-pole array element;

FIGS. 12a-c illustrate three examples of the displacement and spot shapes of the image spots of reflected primary charged particles on the detector for three different driving voltages of an active multi-aperture array;

FIG. 13 illustrates a monitoring method of a multi-beam charged particle microscope including a mirror mode of operation; and

FIG. 14 illustrates a method of calibrating a mirror mode of operation.

### DETAILED DESCRIPTION

WO 2022/033717 A1 is hereby incorporated by reference.

In the description of the embodiments and examples, the same reference signs denote the same features, even if these are not explicitly mentioned in the text. It is to be noted that symbols used in the figures have been chosen to symbolize their respective functionality.

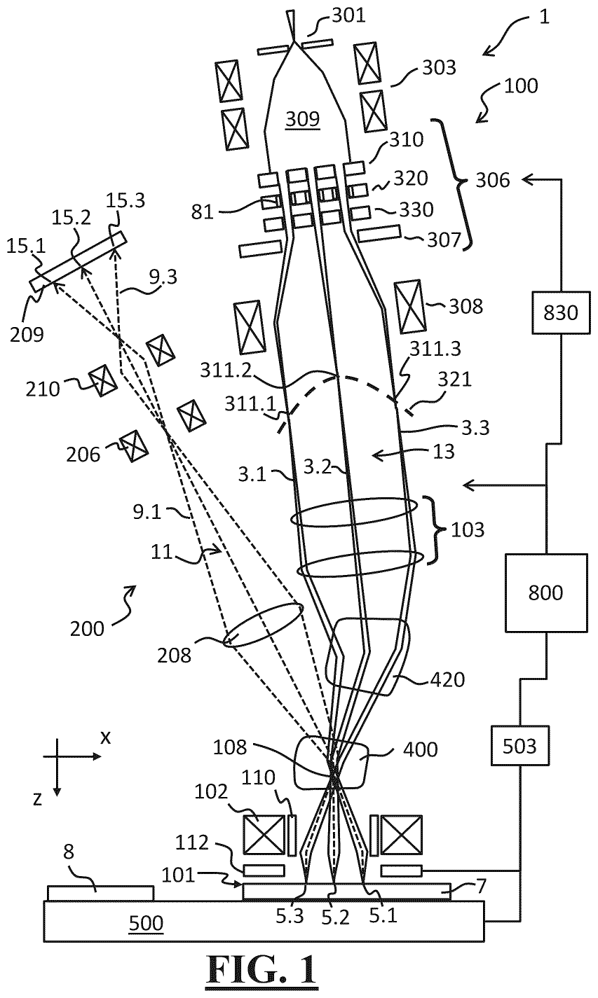

The schematic representation of FIG. 1 illustrates basic features and functions of a multi-beam charged-particle microscopy system 1 according to a normal mode of operation. The type of system shown is that of a multi-beam scanning electron microscope (MSEM or Multi-SEM) using a plurality of J primary electron beamlets 3 for generating a plurality of primary charged particle beam spots 5 on a surface of an object 7, such as a wafer located with a top surface in an object plane 101 of an objective lens 102. For simplicity, only three primary charged particle beamlets 3.1 to 3.3 and three primary charged particle beam spots 5.1 to 5.3 are shown. The features and functions of multi-beamlet charged-particle microscopy system 1 can be implemented using electrons or other types of primary charged particles such as ions, for example Helium ions. Further details of the microscopy system 1 are provided in Patent application PCT/EP2021/066255, filed on Aug. 16.6. 2021, which is hereby fully incorporated by reference.

The microscopy system 1 comprises an object irradiation unit 100 and a detection unit 200 and a beam splitter unit 400 for separating the secondary charged-particle beam path 11 from the primary charged-particle beam path 13. Object irradiation unit 100 comprises a charged-particle multi-beam generator 306 for generating the plurality of primary charged-particle beamlets 3 and is adapted to focus the plurality of primary charged-particle beamlets 3 in the image surface or object plane 101, in which the surface of a wafer 7 is positioned by a sample stage 500. The charged-particle multi-beam generator 306 is adjusted such that the plurality of intermediate focus points 311 of the plurality of primary charged particle beamlets 3 is generated on a spherically curved intermediate image surface 321. It is understood that the intermediate image surface 321 is not a real physical surface, but rather an imaginary surface, which is conjugated to the image surface 101. By forming the plurality of primary charged particle beamlets 3 on the spherically curved intermediate image surface 321, a field curvature and an image plane tilt of the elements of the object irradiation unit 100 downstream of the multi-beam generator 306 are compensated.

The object irradiation unit 100 comprises a source 301 of primary charged particles, for example electrons. The primary charged particle source 301 emits a diverging primary charged particle beam, which is collimated by at least one collimating lens 303 to form a collimated or parallel primary charged particle beam 309. The collimating lens 303 usually includes one or more electrostatic or magnetic lenses, or by a combination of electrostatic and magnetic lenses. The collimating lens 303 may further comprise deflecting elements formed by multi-pole elements not shown in the figure. The collimated primary charged particle beam 309 is incident on the multi-beam generator 306. The multi-beam generator 306 basically comprises a first multi-aperture plate or filter plate 310 illuminated by the collimated primary charged particle beam 309. The first multi-aperture plate or filter plate 310 comprises a plurality of apertures in a raster configuration for generation of the plurality of primary charged particle beamlets 3, which are generated by transmission of the collimated primary charged particle beam 309 through the plurality of apertures. The multi-beamlet generator 306 comprises at least a second multi-aperture plate 320, which is located, with respect to the direction of movement of the electrons in beam 309, downstream of the first multi-aperture or filter plate 310. For example, a second multi-aperture plate has the function of a micro lens array 320, comprising a plurality of ring electrodes 81, each ring electrode 81 set to a defined potential so that the focus positions of the plurality of primary beamlets 3 are individually adjusted in the intermediate image surface 321. In another example, a second active multi-aperture plate can be configured as a deflector of multi-pole array and comprises for example two, four, eight or twelve electrodes for each of the plurality of apertures, for example to deflect each of the plurality of beamlets individually or to act as an array of stigmator elements to individually influence a wavefront aberration of each beamlet.

The multi-beamlet generator 306 is configured with a terminating multi-aperture plate 330. The multi-beamlet generator 306 is further configured with an adjacent electrostatic field lens 307. The field lens 307 is formed as a ring electrode and generates during use an electrical field which is penetrating the apertures of the terminating multi-aperture plate 330. Thereby, a micro-lens array is formed. The field lens 307 further acts as a decelerating or accelerating element and forms a negative or diverging lens element for the plurality of primary beamlets 3. The Together with an optional second field lens 308, the plurality of primary charged particle beamlets 3 is focused and in the intermediate image surface 321, a plurality of focus spots 311 are formed. The multi-beamlet generator 306 is controlled by primary beamlet control module 830, which is connected to the control unit 800 of the microscopy system 1. Further details of a multi-beam generator 306 are disclosed in US patent application US 2019/0259575 and in WO 2021/180365 A1, which are hereby both incorporated by reference.

The intermediate image surface 321 is imaged by field lens group 103 and objective lens 102 into the image plane 101, in which the surface of the wafer 7 is positioned. Thereby, the plurality of primary charged particle beamlets 3 from a cross-over in a back focal plane of the object lens 102. Thereby, a telecentric condition for the primary charged particle beamlets 3 in the image plane 101 is maintained. A decelerating electrostatic field is generated between an electrode 112 and the wafer 7 by application of a voltage to the wafer by the sample voltage supply 503. In this example, a separate electrode 112 is provided between the stage 500 and the objective lens 102. The electrode 112 can also be formed by a tube element enclosing the plurality of beamlets 3. The object irradiation system 100 further comprises a collective multi-beam raster scanner 110 by which the plurality of charged particle beamlets 3 can be deflected in a direction perpendicular to the propagation direction of the charged particle beamlets 3. The propagation direction of the primary beamlets throughout the examples is in positive z-direction. Objective lens 102 and collective multi-beam raster scanner 110 are centred at an optical axis (not shown) of the multi-beam charged-particle system 1, which is perpendicular to wafer surface. The plurality of primary charged particle beamlets 3, forming the plurality of beam spots 5 arranged in a raster configuration, is scanned synchronously over the wafer surface. At each scan position of each of the plurality of primary beam spots 5, a plurality of secondary electrons is generated, respectively, forming the plurality of secondary electron beamlets 9 in the same raster configuration as the primary beam spots 5. The intensity of secondary charged particle beamlets 9 generated at each beam spot 5 depends on the intensity of the impinging primary charged particle beamlet 3, illuminating the corresponding spot 5, the material composition and topography of the object 7 under the beam spot 5, and the charging condition of the object 7 at the beam spot 5. Secondary charged particle beamlets 9 are accelerated by an electrostatic field generated by a sample charging unit 503 between the sample 7 and the electrode 112. The plurality of secondary charged particle beamlets 9 is collected by objective lens 102 and pass the first collective multi-beam raster scanner 110 in opposite direction to the primary beamlets 3. The plurality of secondary charged particle beamlets 9 is then guided by beam splitter unit 400 to follow the secondary beam path 11 of the detection unit 200. The plurality of secondary electron beamlets 9 is travelling in opposite direction from the primary charged particle beamlets 3, and the beam splitter unit 400 is configured to separate the secondary beam path 11 from the primary beam path 13 usually via magnetic fields or a combination of magnetic and electrostatic fields. Optionally, additional magnetic correction elements 420 are present in the primary or in the secondary beam paths.

Detection unit 200 images the plurality of J secondary electron beamlets 9 onto the image sensor 209 to form there a plurality of secondary charged particle image spots 15. The detection unit 200 comprises further electrostatic or magnetic lenses 206, 208 and 210 and further elements, which are not shown. The further elements comprise a scanner for scanning the secondary beamlets such that their positions of the detector are kept invariant. Further elements can be an aperture stop, a multi-aperture array element, or a further beam divider. The detector or image sensor 209 comprises a plurality of detector pixels or individual detectors. For each of the plurality of secondary charged particle beam spots 15.1 to 15.J, the intensity is detected separately, and the material composition of the wafer surface is detected with high resolution for a large image patch of the wafer surface with high throughput.

The raster configuration of the focus spots 5 of the plurality of J primary charged particle 3 can for example be a hexagonal raster of about J=61 or more primary charged particle beamlets 3, for example J=91, J=100, or J >300 beamlets. The primary beam spots 5 have a distance about 6 μm to 15 μm and a diameter of below 5 nm, for example 3 nm, 2 nm or even below. In an example, the beam spot size is about 1.5 nm, and the distance between two adjacent beam spots is 8 μm. For example, with a rectangular raster of 10×10 beamlets with 8 μm pitch, an image patch of approximately 88 μm×88 μm is generated with one image scan with collective multi-beam raster scanner 110, with an image resolution of for example 2 nm or below. The image patch is sampled with half of the beam spot size, thus with a pixel number of 8000 pixels per image line for each beamlet, such that the image patch generated by 100 beamlets comprises 6.4 gigapixel. The digital image data is collected by control unit 800. Details of the digital image data collection and processing, using for example parallel processing, are described in patent application WO 2020/151904 A3 and in US-Patent U.S. Pat. No. 9,536,702, which are hereby incorporated by reference.

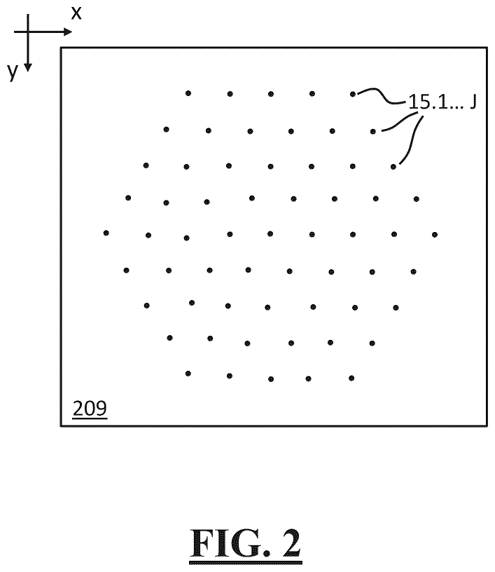

The image sensor 209 includes an array of sensing areas in a pattern compatible to the raster arrangement of the secondary electron beamlets 9 focused by the detection unit 200 onto the image sensor 209. This enables a detection of each individual secondary electron beamlet independent from the other secondary electron beamlets incident on the image sensor 209. The image sensor 209 illustrated in FIG. 1 can be an electron sensitive detector array such as a CMOS or a CCD sensor. Such an electron sensitive detector array can comprise an electron to photon conversion unit, such as a scintillator element or an array of scintillator elements. In another embodiment, the image sensor 209 can be configured as electron to photon conversion unit or scintillator plate arranged in the focal plane of the plurality of secondary electron particle image spots 15. In this embodiment, the image sensor 209 can further comprise a relay optical system for imaging and guiding the photons generated by the electron to photon conversion unit at the secondary charged particle image spots 15 on dedicated photon detection elements, such as a plurality of photomultipliers or avalanche photodiodes (not shown). Such an image sensor is disclosed in U.S. Pat. No. 9,536,702, which is cited above and incorporated by reference. In an example, the relay optical system further comprises a beam splitter for splitting and guiding the light to a first, slow light detector and a second, fast light detector. The second, fast light detector is configured for example by an array of photodiodes, such as avalanche photodiodes, which are fast enough to resolve the image signal of the plurality of secondary electron beamlets 9 according to the scanning speed of the plurality of primary charged particle beamlets 3. The first, slow light detector can be a CMOS or CCD sensor, providing a high-resolution sensor data signal for monitoring the focus spots 15 or the plurality of secondary electron beamlets 9 and for control of the operation of the multi-beam charged particle microscope 1. An image of a hexagonal raster of J=61 secondary beam spots 15.1 . . . 15.J is shown in FIG. 2.

During an acquisition of an image patch by scanning the plurality of primary charged particle beamlets 3, the stage 500 is optionally not moved, and after the acquisition of an image patch, the stage 500 is moved to the next image patch to be acquired. In an alternative implementation, the stage 500 is continuously moved in a second direction while an image is acquired by scanning of the plurality of primary charged particle beamlets 3 with the collective multi-beam raster scanner 110 in a first direction. Stage movement and stage position is monitored and controlled by sensors known in the art, such as Laser interferometers, grating interferometers, confocal micro lens arrays, or similar.

According to an embodiment of the disclosure, a plurality of electrical signals is created and converted in digital image data and processed by control unit 800. During an image scan, the control unit 800 is configured to trigger the image sensor 209 to detect in predetermined time intervals a plurality of timely resolved intensity signals from the plurality of secondary electron beamlets 9, and the digital image of an image patch is accumulated and stitched together from all scan positions of the plurality of primary charged particle beamlets 3.

The multi-beam charged-particle microscopy system 1 of FIG. 1 is configured for a first or normal mode of operation, during which a series of inspection tasks can be performed. In the first or normal mode of operation, an object or wafer 7 is positioned by the stage 500 in the image surface 101 of object irradiation unit 100. The multi-beam charged-particle microscopy system 1 according to the disclosure is further configured for a second or mirror mode of operation, in which by stage 500 an electrostatic mirror 8 is positioned in the image plane 101 of object irradiation unit 100. The mirror element 8 can be mounted on the stage 500 nearby a supporting surface for holding a wafer 7. In another example, the electrostatic mirror 8 can be positioned by a second stage (not shown) under the objective lens 102 during a change of a wafer 7 on the first stage 500.

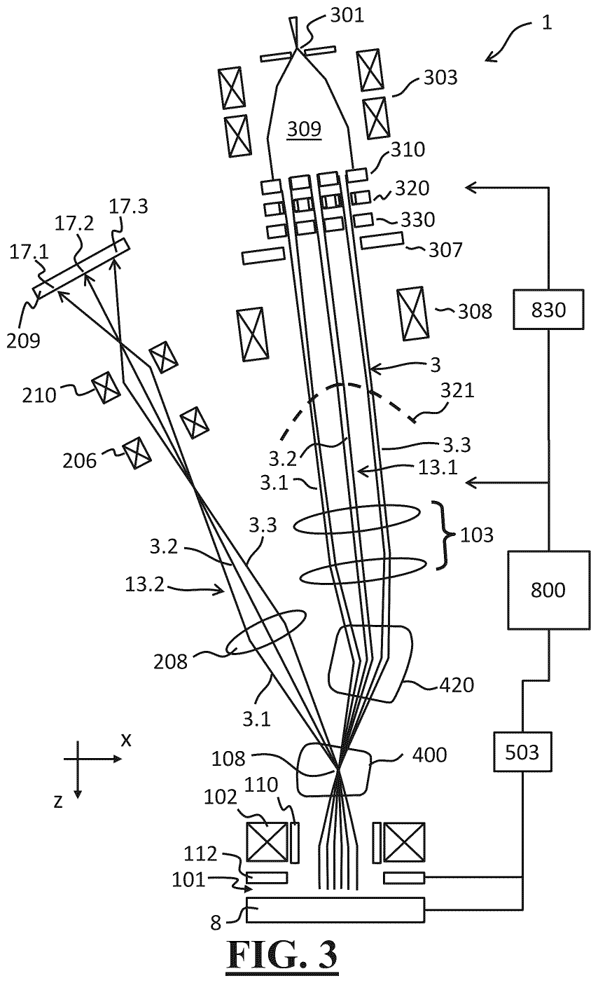

The steps of the second mode of operation are described in more detail below. A first embodiment of the second mode of operation is illustrated in FIG. 3. FIG. 3 shows the same elements of FIG. 1 with the same reference numbers, and reference is made to the description of FIG. 1. In the second mode of operation, the electrostatic mirror 8 is positioned in or close to the image plane 101. However, in the first embodiment, the electrostatic lens 307 is in an off state, such that no focus points 311 are formed in the intermediate image plane 321. Next, a voltage UR>TPE is applied to the mirror 8 which decelerates the primary electrons of the plurality of primary beamlets 3 such that the travelling direction of the primary electrons is reversed. TPE represents thereby the kinetic energy of the primary charged particles when entering the objective lens 102 or electrode 112. The primary electron beamlets 3 are thus reflected at electrostatic mirror 8. The electrostatic mirror 8 can be made of a conductor or having a homogeneous conductive surface, to which the reverting voltage UR is applied. Since the electrostatic mirror 8 does not have an unknown structure as an object or wafer 7, the reverting potential is with high uniformity to all primary beamlets 3. No secondary electrons are generated in the second mode, and the beam divider 400 separates the primary beam-path 13.1 with primary electrons travelling in positive z-direction from the reflected primary electron beam-path 13.2 with reflected primary electrons travelling in negative z-direction. With the voltage UR being approximately equal to the kinetic energy of the primary electrons, the primary electros start at the reversal position with zero kinetic energy and are accelerated similar to the secondary electrons be electrode 112. The detection unit 200 is configured to image the reflected primary electrons on the image sensor 209 to form there a plurality of primary mirror image spots 17. For simplicity, only three primary beamlets 3.1 to 3.3 and three primary mirror image spots 17.1 to 17.3 are shown.

According to the disclosure, the primary beam-path control module 830 is configured to change the voltage of at least a first active multi-aperture element 320 in multiple steps during the second mode of operation. Thereby, for example a focusing power of the primary beamlets is changed during operation in multiple steps and an image performance of the object irradiation unit 100 can be investigated from a stack of images through the focus of the plurality of primary charged particle beamlets. According to the disclosure, the control unit 800 is configured to acquire a stack of mirror images, wherein for each of the mirror images, a parameter, for example a voltage parameter of a multi-aperture device is changed. Thereby, for example a focus stack of mirror images is obtained. The control unit is further configured to evaluate a focus stack of mirror images and derive an imaging performance of the object irradiation unit 100 from the focus stack. More on the configuration and the method of operation in the second or mirror mode is described below.

According to the method of operation in the second or mirror mode, a wafer surface with an unknown structure is replaced by an electrostatic mirror element 8 with a known structure. Ideally, the electrostatic mirror element 8 comprises a planarized electrode layer of a conductive material, covered by an isolating protection layer. Via the voltage supply unit 503, a decelerating voltage UR is provided to the electrode layer of the electrostatic mirror element 8 to generate a decelerating electrical field. The decelerating electrical field decelerates the primary electrons of first primary beam path 13.1 and prevents the primary electrons from reaching the electrostatic mirror element 8. At a point of return, the primary electrons have no kinetic energy and are accelerated by the decelerating field in opposite direction (in der coordinate system of FIG. 3 in negative z-direction), until the primary electrons reach a kinetic energy similar to the secondary electrons of the first or normal mode of operation. In an example, the electrostatic mirror element 8 is placed by stage 500 at a larger distance to the electrode 112 or objective lens 102, below the image plane 101 for the first or normal mode of operation. Thereby, the field gradient is reduced, and a smoother deceleration or acceleration of the primary electrons is generated. Therefore, the control unit 800 can further be configured to move in the z-distance and to position the surface of the wafer 8 during the first or normal mode of operation in a first z-distance corresponding to the image plane 101, and to position the surface of the electrostatic mirror element 8 during the second or mirror mode of operation in a second, larger z-distance.

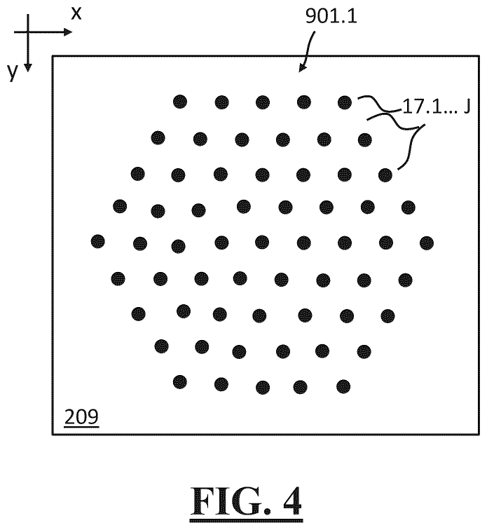

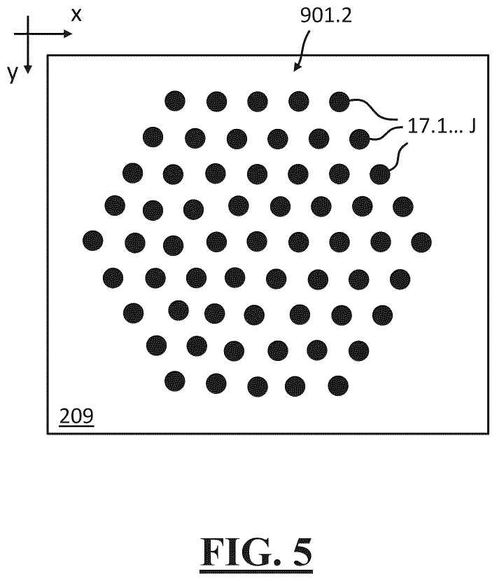

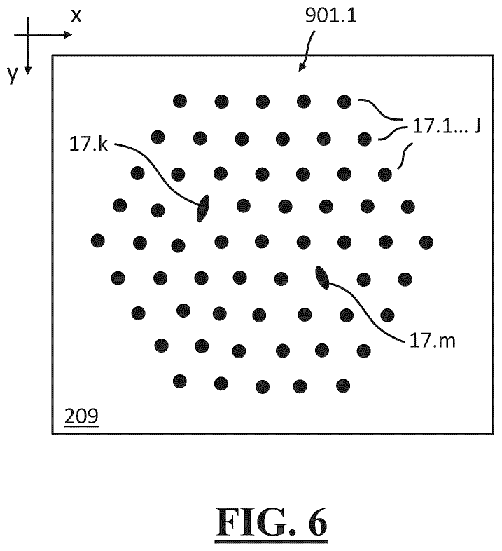

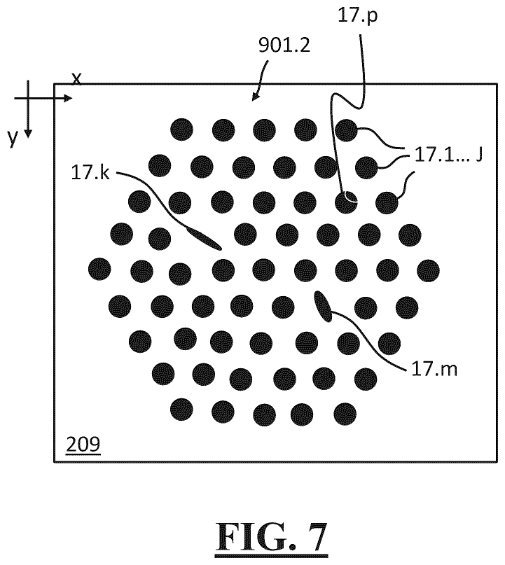

According to the example of FIG. 3, the switching off of the lens electrode 307 and lens 308, the propagating direction of the primary beamlets is unchanged. In the example of FIG. 3, with a collimated incident beam 309, the primary beamlets formed by the filter plate are propagating parallel with a smaller distance compared to the normal mode of operation. In this example it is possible to adjust the magnification of the detection unit 200 such that the reflected electron beam spots 17 are at the same positions as the secondary electron beam spots 15 in FIG. 1. FIGS. 4 and 5 show two example images 901.1 and 901.2 of an image stack of the reflected electron beam spots 17.1 to 17.J of J=61 primary electron beamlets at a first and a second voltage offset of the first active multi-aperture element 320. Due to the difference in voltage offset applied to the ring electrodes 81 of the first active multi-aperture element 320, a slightly different focusing power is introduced into the primary beamlets, leading to a different diameter of the reflected electron beam spots 17.1 to 17.J. FIGS. 6 and 7 show two example images 901.1 and 901.2 of an image stack of the reflected electron beam spots 17.1 to 17.J of J=61 primary electron beamlets at a first and a second voltage offset of the first active multi-aperture element 320. In the last example, some primary beamlets show a deviation from an ideal behaviour. For example, in image 901.1, two beam spots 17.k and 17.m have an elliptical shape. With the second image, the beam spots can be further investigated, and a shape deviation of an aperture can be distinguished from an astigmatism. Spot 17.m does not change its orientation through focus, therefore the elliptical shape of spot 17.m arises probably from a shape deviation of an aperture of the filter plate 310. On the other hand, spot 17.k changes the orientation of the elliptical shape through focus (between the two images 6 and 7), which serves as an indication that beamlet with index k suffers from an astigmatism. A further beamlet 17.p shows a defect, which is hardly visible in the first picture 17.3. The defect can be a particle or contamination of an aperture, which is only visible in the defocussed state of image 901.2.

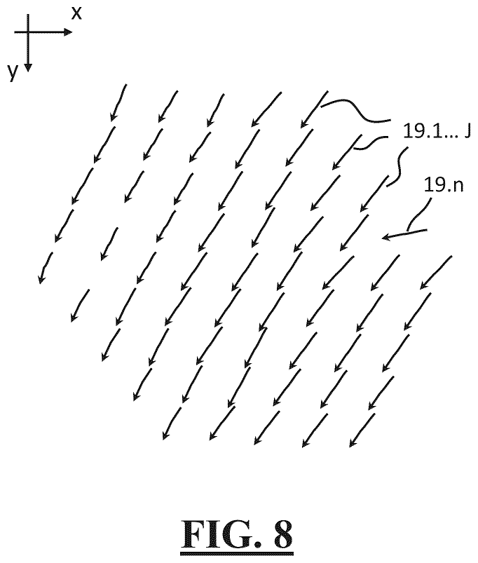

Beside the extraction of an astigmatism of a primary beamlet, further aberrations of beamlets can be derived from a stack of images. Other aberrations can be a spherical aberration, a coma aberration, or a telecentricity property. An example of a telecentricity aberration is shown in FIG. 8. For each beam spot 17, a centre of gravity is determined in each of the images of the stack of images and the trajectory of the centres of gravity of the voltage parameter is recorded through the image stack. The trajectories 19.1 to 19.J are shown as paths, with the arrows pointing in positive voltage direction. An average trajectory can be computed and outlies, such as outlier 19.n can be determined. An average trajectory corresponds to a first order telecentricity aberration, given for example by a tilt of the plurality of primary beamlets deviating from a surface normal to the electrostatic mirror 8. The outlier 19.n can have its origin in a defect of a ring electrode 81 of the multi-aperture plate 320. A telecentricity aberration can also arise from a misalignment of the stack of multi-aperture plates 310, 320 and/or 330.

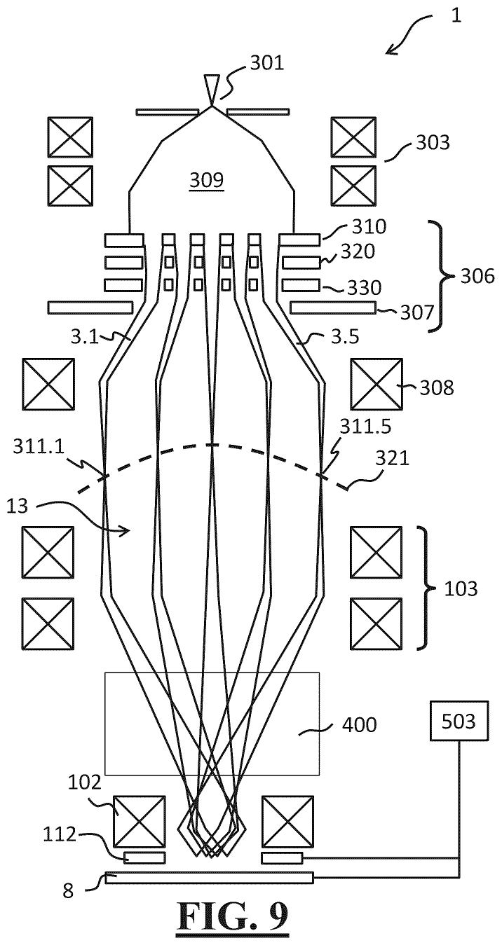

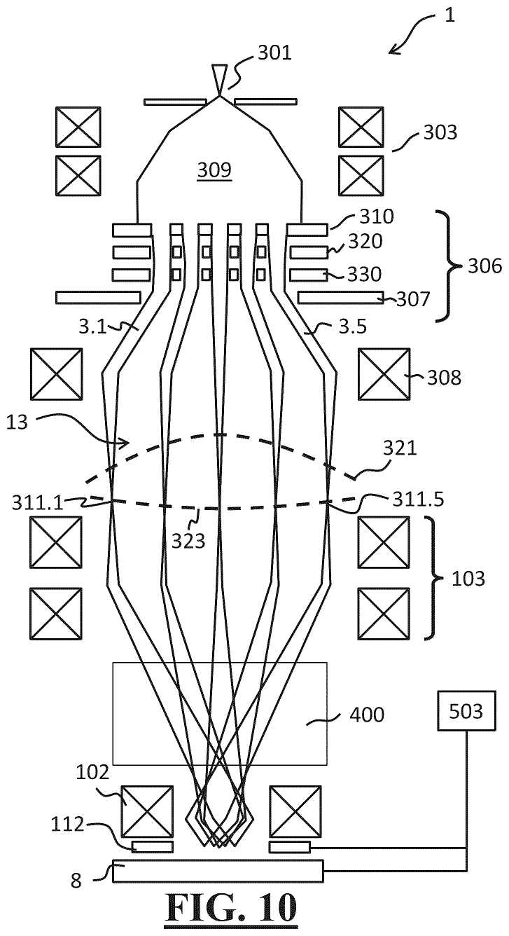

According to the first embodiment, an image stack is recorded with a field lens electrode 307 in an off state. In a second embodiment, an image stack is recorded with a field lens electrode 307 in an on state, thus a focus stack is generated for each primary beam spot in reflection or mirror mode. FIG. 9 shows an example of the multi-beamlet charged-particle microscopy system 1 during use in a first or standard focus position, when the primary intermediate focus spots 311 coincide with intermediate surface 321. FIG. 10 shows an example of the multi-beamlet charged-particle microscopy system 1 during use in a second focus position with the first active multi-aperture element 320 switched off. The primary intermediate focus spots 311 a placed downstream of the intermediate surface 321 into a defocused imaginary surface 323. With different activation of the first active multi-aperture element 320, a series of different focus positions can be achieved, and thereby a focus stack of the reflected primary beamlets is recorded.

In the examples above, all elements of an active multi-aperture array element 320 are changed in parallel and for example a change of focus positions from plane 321 to plane 323 is achieved for all beamlets. However, it is also possible to analyse only single beamlets and only change the corresponding electrodes of the active multi-aperture array element 320.

In the example of FIG. 10, when a focus stack through the focus points of the primary beamlets 3 is performed, it is advantageous to magnify the imaging ratio in the detection unit 200 (see FIG. 1 or 3) to achieve a very large magnification. With a large magnification, small changes of reflected primary electron focus spots 17 through focus can be detected. In this case, it is possible that not all of the reflected primary electron spots can be detected by detector 209.

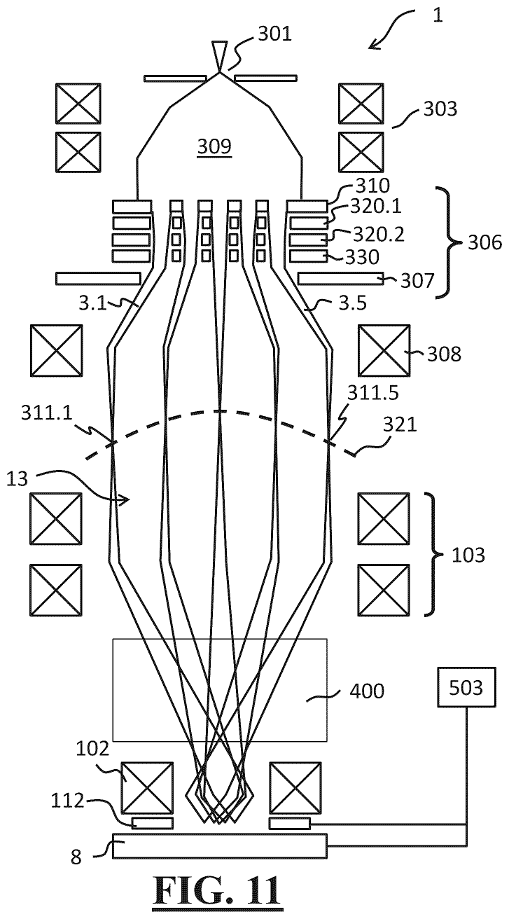

FIG. 11 illustrates another example, in which a second active multi-aperture element 302.2 is present downstream of the first active multi-aperture element 302.1. The second active multi-aperture element 302.2 is configured as a multi-pole array element, by which each primary beamlet can be influenced individually, for example a beamlet can be deflected or an aberration of a beamlet can be compensated or introduced. In this example, the second active multi-aperture element 302.2 is changed for the recording of image stack. Thereby, an aberration of each primary beamlet can be determined.

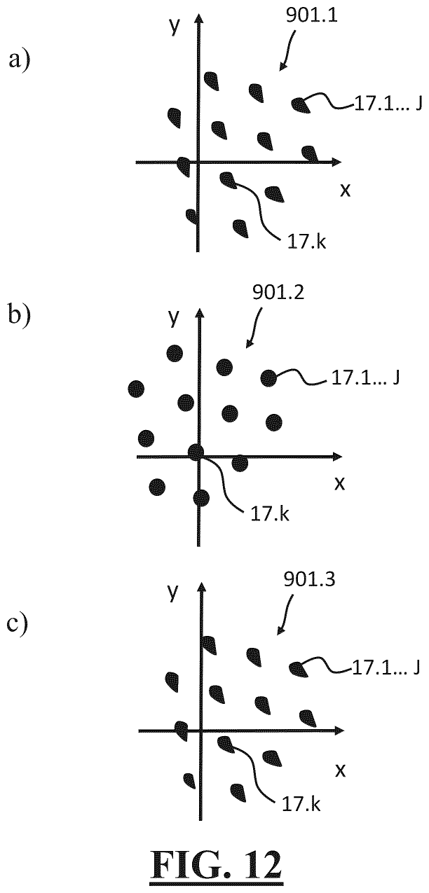

An example of a stack of images according to the examples of the second embodiment is illustrated schematically in FIGS. 12a-c. During acquisition of a first reflected electron image 901.1 of FIG. 12a), a first voltage of for example 20V is applied to the electrodes 81 of the active multi-aperture plate 320 or 320.1. During acquisition of a second reflected electron image 901.2 of FIG. 12b), a second voltage of for example 50V is applied to the electrodes 81 of the active multi-aperture plate 320 or 320.1. During acquisition of a third reflected electron image 901.3 of FIG. 12c), a third voltage of for example 80V is applied to the electrodes 81 of the active multi-aperture plate 320 or 320.1. Due to the change of voltage, a change in a constant or field-invariant Coma aberration is visible in the first or third reflected electron image 902.1 and 901.3. A constant or field-invariant coma aberration is typically introduced or compensated by a tilt or a displacement of a global optical element of a multi-beam charged particle microscope 1, such as field lenses 308, 103 or objective lens 102. A constant or field-invariant Coma can also be introduced or compensated by an improper adjustment or calibration of the beam divider 400 or electromagnetic compensation element 420. A small coma aberration may not be visible in the Coma-shaped spots 17, especially at the ideal focus position of images 901.2. A Coma aberration can also be detected from a symmetric displacement of the reflected primary electron images though focus. An example is illustrated at spot 17.k, which corresponds to the axial beam at the ideal focus position in reflected primary electron image 901.2, and which is laterally shifted in the same direction in each of the reflected primary electron image 901.1 and 901.3 with different focus positions. For better illustration, the effect is highly exaggerated in FIG. 12.

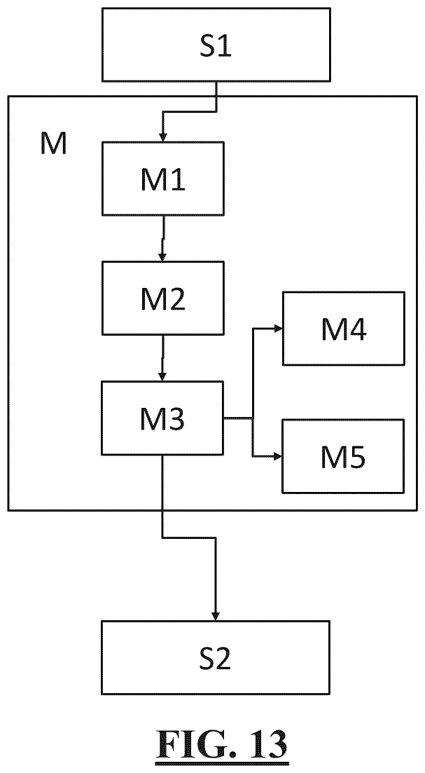

Operating the multi-beam charged particle microscope system 1 in the mirror mode of operation offers the advantage that it is possible to inspect or check the functionality of the micro-optical unit 306 overall. The improved mirror mode of operation according to the disclosure therefore provides an efficient method of monitoring a multi-beam charged particle inspection system during a wafer inspection task. According to a third embodiment of the disclosure, a method of monitoring a multi-beamlet charged-particle microscopy system 1 is given. The method is illustrated in FIG. 13. In step S1, a first or normal imaging operation of the multi-beam charged particle microscope system 1 is performed. A wafer 7 is loaded and placed with the stage 500 in the image plane 101 of the multi-beam charged particle microscope system 1 and a series of inspection tasks is performed. For example, during the exchange of wafer 7, the mirror element 8 is positioned in proximity of the image plane 101 and the metrology or monitoring step M is performed. During metrology step M1, the setup and the control parameters for controlling the multi-beam charged particle microscope system 1 are changed by control unit 800 from the first to the second or mirror imaging mode. For example, the driving voltage of electrode 307 is switched off, and the magnification of detection unit 200 is adjusted. The controller 800 of the multi-beam charged particle microscope system 1 is configured to control the detection unit 200 to set a magnification during the imaging in second or mirror imaging mode. The projection lenses 206, 208 and 210 of the detection unit 200 are typically operated at a few 100 mA and up to approximately at most 2000 mA. The lenses of detection unit 200 are controlled by the control unit 800 and the control unit 800 triggers a change of the driving currents of the magnetic lens elements 206, 208 and/or 210 of detection unit to adjust the magnification. Furthermore, the control unit 800 triggers the sample voltage supply 503 to provide the voltage UR to the mirror element 8.

During step M2, a series of L mirror images 901 is recorded, wherein for each mirror image 901.1 to 901.L, at least one driving voltage of an active multi-aperture array is changed according to a predetermined set driving voltages. For example, a driving voltage of the plurality of ring electrodes of the first multi-aperture array 320, 320.1 is changed. A stack of images with for example increasing driving voltage, corresponding to increasing focusing power, is recorded. Generally, no scanning operation is required during step M2 and the deflection scanner 110 is in an off state. However, it is also possible to obtain a stack of reflected primary electron images 901.1 to 901.L at a predetermined scanning position. Thereby, aberrations in dependency of a scanning position can be determined.

In step M3, the stack of mirror images 901.1 to 901.L is analysed and an image performance is determined for at least one of the primary beamlets 3. The image performance is for example an astigmatism aberration of an individual beamlet 3, a defect of an aperture of any of the multi-aperture plates 310, 320 or 330, a telecentricity aberration or other aberrations or defects.

The result of the determination can trigger a calibration step M4, during which new control parameters of the multi-beam charged particle microscope system 1 are determined, by which aberrations determined in step M3 are compensated.

The result of the determination can trigger a cleaning step M5, by which aberrations determined in step M3 are compensated. In an example, a defect arising from a charging effect or a contamination of the multi-aperture plates is repaired by a discharging or cleaning of the multi-aperture plates.

In step S2, the inspection task is continued with for example a next wafer. The next wafer is positioned with stage 500 in the image plane 101 and the control unit 800 switches the multi-beam charged particle microscope system 1 into normal mode of operation, optionally with the new control parameters determined in step M4.

In an example, step M3 comprises the extraction of centroid positions of at least one of a plurality of primary charged particle beamlets in each of the mirror images of the stack of L mirror images. The extraction of centroid positions can for example be obtained by filtering and image processing methods known in the art, for example by a thresholding operation and by morphologic operations. In an example, extraction of centroid positions can be obtained by algorithms or software instructions including machine learning algorithms. Form the centroid positions, higher order aberration of the at least one primary charged particle beamlets can be determined. For example, from a linear displacement through focus, a telecentricity aberration can be determined. For example, from a symmetrical change of position with respect to a focus plane, a coma aberration can be determined (see for example FIG. 12 and the corresponding explanation of FIG. 12).

In an example, step M3 comprises extracting the focus spot diameters of at least one of the plurality of primary charged particle beamlets in each of the mirror images of the stack of L mirror images, and determining an ideal focus position of the at least one primary charged particle beamlet. In an example, step M3 comprises determining a field curvature of the focus positions of the plurality of primary charged particle beamlets.

In an example, step M3 comprises extracting the focus spot shapes of at least one of the plurality of primary charged particle beamlets in each of the mirror images of the stack of L mirror images. In an example, step M3 comprises determining an astigmatism of the at least one primary charged particle beamlets.

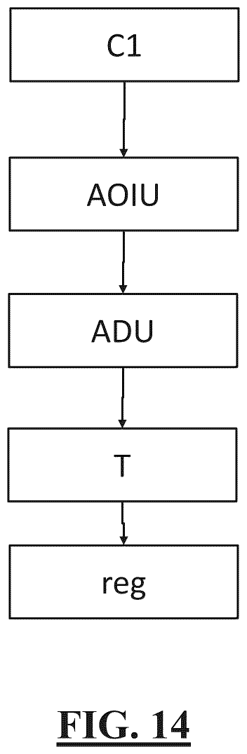

The monitoring and calibration of a multi-beam charged particle microscope 1 according to the disclosure generally uses a proper calibration or the second or mirror mode of operation. A method of calibrating a second or mirror mode of operation according to the fourth embodiment is described in FIG. 14. In a first step C1, a second or mirror mode of operation is selected. In a first example, the second or mirror mode of operation is selected according to the first embodiment with a focusing lens electrode 307 in an off state. In a second example, the second or mirror mode of operation is selected according to the second embodiment. The electrostatic mirror 8 is placed by stage 500 in a distance to the image plane 101 and a decelerating voltage UR is provided to the mirror element 8 by voltage supply unit 503. The decelerating voltage UR is selected slightly larger compared to the kinetic energy TPE of the primary electrons after leaving the objective lens 102, for example UR=TPE+50V.

In a second step AOIU, the object irradiation unit 100 is adjusted. For a proper reflection mode, the plurality of primary charged particle beamlets 3 propagates in parallel direction through the decelerating or reflecting field between electrode 102 und mirror electrode 8. This condition of telecentricity is achieved when the plurality of primary charged particle beamlets 3 form a cross over in the back focal plane 108 of the objective lens 102. During the second step AOIU, the field lenses such as field lenses 308 and 103 are adjusted that plurality of primary charged particle beamlets 3 form a cross over in the back-focal plane 108 and a telecentric bundle of beamlets is formed. This can be verified by for example changing the z-distance of the mirror element 8 by the stage 500. The reflected primary electron beamlets may not change their position at image sensor 209 while the mirror 8 is moved. The second step AOIU of adjusting the object irradiation unit 100 can comprise further steps, such as changing the magnification by which the object irradiation unit 100 images the intermediate image plane 321 into the image plane 101.

In a third step ADU, the detection unit 200 is adjusted. In an example, the magnification of the imaging of the reflected primary beamlets in the second beam path 13.2 is adjusted. In an example, the magnification is adjusted by lenses 206, 208 and 210 such that the reflected electron image spots 17.1 to 17.J coincide with the positions of the secondary electron image spot 15.1 to 15.J during the normal mode of operation. In a second example according to the second embodiment, the magnification is further increased to increase the resolution for at least some of the reflected electron image spots 17. Thereby, aberrations of the reflected electron image spots 17 can better be resolved through the image stack. Other adjustments of the detection unit 200 might be used due to the small differences between the kinetic energy of secondary electrons in normal mode of operation and of reflected electrons in the mirror mode of operation.

In a fourth step T, the mirror mode operation is tested. The L driving voltages and the driving voltage range provided to the electrodes 81 of an active multi-aperture element 302, 302.1 or 302.2 are determined. A stack of reflected primary electron images 901.i to 901.L is recorded and evaluated. The number L of driving voltages can be 2 or more, for example L=3 or L=5. Typically, it is not required to obtain more than L=5 images for an image stack. The range of driving voltage variation is determined according to an effect of an expected aberration, such that an aberration or defect can be determined with sufficient accuracy. For example, a difference between two driving voltages for a micro-lens ring electrode 81 of an active multi-aperture plate 320, 302.1 is selected to be about 20V or more, and for example 5 driving voltages are selected in a driving voltage range between 0V and 100V or 150V. For example, a difference between two driving voltages for a multi-pole electrode 81 of an active multi-aperture plate 320.2 is selected to be about 2V or 3V, and for example five driving voltages are selected in a driving voltage range between-6V and +6V. However, the driving voltages generally depend on the design of the active multi-aperture plates 320 and different driving voltage steps and ranges can be used.

In a fifth step reg, the parameters and setup values of the object irradiation unit 100, the detection unit 200 and the driving voltages are registered and stored in a memory for further use during a second mode of operation.

### A LIST OF REFERENCE NUMBERS IS PROVIDED

1 multi-beamlet charged-particle microscopy system
3 primary charged particle beamlets, or plurality of primary charged particle beamlets
5 primary charged particle beam spot
7 object or wafer
8 mirror element
9 secondary electron beamlet, forming the plurality of secondary electron beamlets
11 secondary electron beam path
13 primary beam path
15 secondary charged particle image spot
17 primary mirror image spots
19 image spot trajectories
81 electrode
100 object irradiation unit
101 object or image plane plane
102 objective lens
103 field lens group
108 beam cross over or back focal plane
110 collective multi-beam raster scanner
112 electrode
200 detection unit
206 electrostatic lens
208 imaging lens
209 image sensor
210 imaging lens
301 charged particle source
303 collimating lenses
306 primary multi-beamlet forming unit
307 first field lens
308 second field lens
309 primary electron beam
310 filter plate
311 primary electron beamlet spots
320 active multi-aperture plates
321 intermediate image surface
323 defocused image plane
330 terminating multi-aperture plate
400 beam splitter unit
420 correction element
500 sample stage
503 Sample voltage supply
800 control unit
830 primary beam-path control module
901 images of image stack

What is claimed is:

1. A method, comprising:
switching a multi-beam charged particle microscope from a first mode of operation to a mirror mode of operation, switching comprising positioning an electrostatic mirror element in proximity to an image plane of the multi-beam charged particle microscope and controlling a voltage of the electrostatic mirror element to correspond to a kinetic energy of primary charged particles of primary charged particle beamlets generated by the charged particle microscope;
changing a driving voltage of at least one electrode of an active multi-aperture array element of the multi-beam charged particle microscope;
acquiring a stack of mirror images of primary charged particles reflected by the electrostatic mirror, each mirror image corresponding to a different driving voltage; and
determining an image performance of at least one primary charged particle beamlet from the stack of mirror images.

2. The method of claim 1, wherein switching from the first mode to the mirror mode further comprises:
switching off a focusing power of a field lens of the multi-beam charged particle microscope; and/or
changing a magnification of a detection unit of the multi-beam charged particle microscope.

3. The method of claim 1, wherein the active multi-aperture array element comprises an array of ring electrodes configured to change a focusing power of an array of micro-lenses defined by the active multi-aperture array element.

4. The method of claim 1, wherein the active multi-aperture array element comprises an array of multi-pole elements configured to change an astigmatism or a deflection angle of at least one primary charged particle beamlet for each image mirror image.

5. The method of claim 1, comprising:
acquiring a first mirror image of the stack of mirror images at a first driving voltage; and
acquiring a second mirror image of the stack of mirror images at a second driving voltage,
wherein the second driving voltage differs from the first driving voltage by more than 10% of a voltage range of the driving voltage provided to the at least one electrode.

6. The method of claim 1, further comprising, in each of at least some of the mirror images:
extracting centroid positions of at least one primary charged particle beamlet in the mirror image; and
determining a higher order aberration of the at least primary charged particle beamlet from the centroid positions within the mirror image.

7. The method of claim 1, further comprising, in each mirror image:
extracting centroid positions of at least one primary charged particle beamlet in the mirror image; and
determining a higher order aberration of the at least primary charged particle beamlet from the centroid positions within the mirror image.

8. The method of claim 7, wherein the higher order aberration comprises telecentricity aberration or a coma aberration.

9. The method of claim 1, further comprising, in each of at least some of the mirror images:
extracting focus spot diameters of at least one primary charged particle beamlet in the mirror image; and
determining an ideal focus position of the at least one primary charged particle beamlet.

10. The method of claim 1, further comprising, in each mirror image:
extracting focus spot diameters of at least one primary charged particle beamlet in the mirror image; and
determining an ideal focus position of the at least one primary charged particle beamlet.

11. The method of claim 10, determining a field curvature of the focus positions of the plurality of primary charged particle beamlets.

12. The method of claim 1, further comprising, in each of at least some of the mirror images:
extracting focus spot shapes of at least one primary charged particle beamlet in the mirror image; and
determining a higher aberration of the at least one primary charged particle beamlet.

13. The method of claim 1, further comprising, in each mirror image:
extracting focus spot shapes of at least one primary charged particle beamlets in the mirror image; and
determining a higher aberration of the at least one primary charged particle beamlet.

14. The method of claim 13, comprising determining an astigmatism of the at least one primary charged particle beamlet.

15. The method of claim 1, further comprising) triggering a calibration of the multi-beam charged particle microscope and/or triggering cleaning of the multi-beam charged particle microscope.

16. A method of operating a multi-beam charged particle microscope, the method comprising:
in a mirror mode of operation of the multi-beam charged particle microscope, selecting a decelerating voltage to exceed a kinetic energy of primary electrons when exiting an objective lens or a final electrode of the multi-beam charged particle microscope;
providing the decelerating voltage to a sample stage of the multi-beam charged particle microscope to generate a decelerating electrical field below the objective lens or the final electrode of the multi-beam charged particle microscope;
adjusting an object irradiation unit to achieve a telecentric bundle formed by a plurality of primary charged particle beamlets in the decelerating electrical field; and
adjusting a magnification of a detection unit to form a plurality of reflected primary electron beam spots on a detector.

17. The method according to claim 16, further comprising:
selecting a sequence of driving voltages within a voltage range; and
recording a stack of primary electron mirror images with the detector,
wherein during each recording, a driving voltage of the sequence of driving voltages is applied to at least one electrode of an active multi-aperture element of the multi-beam charged particle microscope.

18. One or more machine-readable hardware storage devices comprising instructions that are executable by one or more processing devices to perform operations comprising the method of claim 1.

19. A system comprising:
one or more processing devices; and
one or more machine-readable hardware storage devices comprising instructions that are executable by the one or more processing devices to perform operations comprising the method of claim 1.

20. The system of claim 19, further comprising:
a multi-beam charged particle microscope, comprising:
a stage;
an electrostatic mirror supported by the stage;
a voltage supply unit configured to provide a voltage the electrostatic mirror;
an active multi-aperture array comprising at least an electrode configured to individually influence each primary charged particle beamlet during use of the multi-beam charged particle microscope; and
a detection unit comprising a plurality of charged particle lenses, wherein the control unit is configured to adjust a magnification of the detection unit when the multi-beam charged particle microscope is in the mirror mode.
